(19) United States
(12) Patent Application Publication
(10) Pub. No.: US 2017/0077443 A1
(43) Pub. Date: Mar. 16, 2017

(54) PACKAGING METHOD, DISPLAY PANEL, DISPLAY DEVICE AND PACKAGING APPARATUS

(71) Applicants: BOE TECHNOLOGY GROUP CO., LTD., Beijing (CN); ORDOS YUANSHENG OPTOELECTRONICS CO., LTD., Ordos (CN)

(72) Inventor: Zhiliang JIANG, Beijing (CN)

(21) Appl. No.: 15/137,360

(22) Filed: Apr. 25, 2016

(30) Foreign Application Priority Data
Sep. 15, 2015 (CN) 201510587460.3

(51) Int. Cl. H01L 51/52; H01L 51/56

(52) U.S. Cl. CPC H01L 51/5246; H01L 51/56

(57) ABSTRACT

A packaging method comprising forming a frit on a first substrate, affixing a second substrate to the first substrate in position, and irradiating the frit by laser beam so as to melt the frit. The packaging method further comprises performing an ultrasonic treatment on the frit by means of ultrasonic wave when the frit being melted. A display panel packaged by the packaging method and a display device having the display panel are disclosed. Further, a packaging device for performing the packaging method is also disclosed.

### TECHNICAL FIELD

Embodiments of the present disclosure relate to a packaging method, a display panel, a display device and a packaging apparatus.

### BACKGROUND

In recent years, Organic Light-Emitting Diode (OLED) display, which is a newly-developed flat panel display, has attracted wide attention. However, a conventional OLED, especially electrodes with low work function and an organic function layer disposed therein, would be easily affected by oxygen and water vapor in the ambient environment and would be deteriorated in performance, thereby severely affecting the service life of the OLED. If an OLED device is sealed in an environment without water and oxygen, the service life of the display can be significantly prolonged. Therefore, packaging technology of OLED device becomes an important process to improve the life of the OLED display device and thus it is a task to be urgently fulfilled that an effective packaging technology is researched and developed so that oxygen and water vapor can be obstructed.

At present, in packaging cover glass, a frit is typically used to perform the packaging between the cover glass and the array substrate (TFT substrate). By depositing the frit on a packaging region of the array substrate and heating the frit by a heat source such as a laser beam when the cover glass and the array substrate are affixed in position, the frit is heated to melt so that the cover glass and the array substrate are packaged together. However, in the above-described packaging process, air bubbles are prone to be generated in the frit, thereby affecting the packaging yield.

### SUMMARY

Embodiments of the present disclosure provided a packaging method capable of reducing the amount of air bubbles generated in the frit during the packaging process.

At least one embodiment of the present disclosure provides a packaging method comprising forming a frit on a first substrate, affixing a second substrate to the first substrate in position, and irradiating the frit by laser beam to melt the frit, wherein the method further comprises performing an ultrasonic treatment on the frit by means of ultrasonic wave when the frit being melted.

In one embodiment of the present disclosure, the ultrasonic wave has a frequency in a range of 20 kHz to 60 kHz.

In one embodiment of the present disclosure, the first substrate is an OLED array substrate and the second substrate is a cover glass.

In one embodiment of the present disclosure, the frit is irradiated by the laser beam from a side of the second substrate away from the first substrate, and the ultrasonic treatment is performed on the frit by use of the ultrasonic wave from a side of the first substrate away from the second substrate.

At least one embodiment of the present disclosure further provides a display panel comprising a first substrate and a second substrate which are packaged together through the method as described above.

At least one embodiment of the present disclosure further provides a display device comprising the display panel as described above.

At least one embodiment of the present disclosure further provides a packaging apparatus comprising a laser emitting device configured to emit a laser beam for irradiating a frit between a first substrate and a second substrate so as to melt frit, and further comprising an ultrasonic treatment device configured to perform an ultrasonic treatment on the frit by ultrasonic wave when the frit being melted.

In one embodiment of the present disclosure, the packaging apparatus further comprises a control device configured to control the power of the laser beam and the frequency of the ultrasonic wave.

In one embodiment of the present disclosure, the ultrasonic treatment device is an ultrasonic vibration generator.

In the packaging method according to the embodiments of the present disclosure, by performing the ultrasonic treatment on the frit when the frit being melted, by virtue of the cavity effect of ultrasonic wave vibration, an air bubble in the melted frit has its diameter and rising speed continuously increased so that the air bubble is discharged rapidly from the frit and the packaging yield is thus improved.

### BRIEF DESCRIPTION OF THE DRAWINGS

In order to clearly illustrate the technical solutions of the embodiments of the disclosure, the drawings of the embodiments will be briefly described in the following; it is obvious that the drawings described below are only related to some embodiments of the disclosure and thus are not limitative of the disclosure.

FIG. 1 is a flow chart of a packaging method according to one embodiment of the present disclosure;

FIG. 2 is an illustrative view of packaging according to one embodiment of the present disclosure; and

FIG. 3 is an illustrative view of the packaging apparatus according to one embodiment of the present disclosure.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

At least one embodiment of the present disclosure provides a packaging method comprising forming a frit on a first substrate, affixing a second substrate to the first substrate in position, and irradiating the frit by a laser beam to melt the frit, wherein the packaging method further comprises performing an ultrasonic treatment on the frit by means of ultrasonic wave when the frit being melted.

In the packaging method provided by the embodiments according to the present disclosure, by performing the ultrasonic treatment on the frit when the frit being melted, by virtue of the cavity effect of ultrasonic wave vibration, an air bubble in the melted frit has its diameter and rising speed continuously increased so that the air bubble is discharged rapidly from the frit and the packaging yield is thus improved.

The above-described packaging method according to the embodiments of the present disclosure can be utilized in packaging an OLED display device. The first substrate can be a cover glass or can be an OLED array substrate. If the first substrate is a cover glass, the second substrate is an OLED array substrate. If the first substrate is an OLED array substrate, the second substrate is a cover glass.

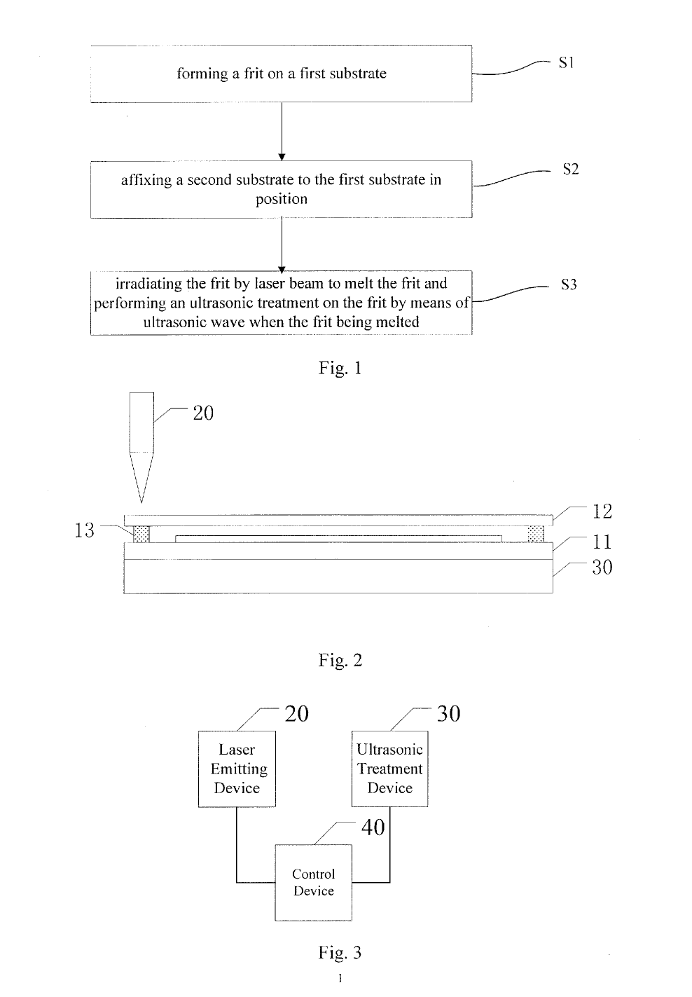

FIG. 1 illustrates a flow chart of the packaging method according to one embodiment of the present disclosure. The packaging method comprises:

forming a frit on a first substrate, for example, the first substrate can be an OLED array substrate and the frit can be formed on a packaging region of the OLED array substrate;

affixing a second substrate to the first substrate in position, the second substrate being a cover glass; and

irradiating the frit by a laser beam to melt the frit and performing an ultrasonic treatment on the frit by means of ultrasonic wave when the frit being melted.

Referring to FIG. 2, since a periphery circuit is usually formed in the packaging region of the OLED array substrate, a laser emitting device 20 can be disposed on a side of the second substrate 12 away from the first substrate 11, from which side the frit 13 is irradiated by a laser beam. The ultrasonic treatment device 30 is disposed on a side of the first substrate 11 away from the second substrate 12, from which side the frit 13 is subjected to ultrasonic treatment when the frit being melted. When the ultrasonic treatment being performed, due to cavity effect of ultrasonic wave vibration, a tiny air bubble in the melted frit has its diameter and rising speed continuously increased and finally reaches an interface between the frit 13 and the second substrate 12 and is discharged rapidly, so that air bubbles in the frit are reduced and the packaging yield is improved.

In one embodiment of the present disclosure, the frequency of the ultrasonic wave can be from 20 kHz to 60 kHz. For example, it can be 30 kHz, 40 kHz, 50 kHz and etc..

At least one embodiment of the present disclosure further provides a display panel comprising a first substrate and a second substrate which are packaged together by the above-described packaging method.

In one embodiment of the present disclosure, the first substrate can be a cover glass or an OLED array substrate. If the first substrate is a cover glass, the second substrate is an OLED array substrate. If the first substrate is an OLED array substrate, the second substrate is a cover glass.

At least one embodiment of the present disclosure provides a display device comprising the display panel as described above. The display device according to the embodiments of the present disclosure can be any product or component having display function such as a display screen of a laptop, a display, a television, a digital photo frame, a cell phone, a tablet PC and the like.

At least one embodiment of the present disclosure further provides a packaging apparatus comprising a laser emitting device configured to emit laser beam for irradiating a frit between a first substrate and a second substrate so as to melt the frit. The packaging apparatus further comprises an ultrasonic treatment device configured to perform an ultrasonic treatment on the frit by ultrasonic wave when the frit being melted.

FIG. 3 is an illustrative view of the packaging apparatus according to one embodiment of the present disclosure. The packaging apparatus comprises:

a laser emitting device 20 configured to emit laser beam for irradiating a frit between a first substrate and a second substrate so as to melt the frit;

an ultrasonic treatment device 30, for example an ultrasonic vibration generator, configured to perform an ultrasonic treatment on the frit by ultrasonic wave when the frit being melted;

a control device 40, connected with the laser transmitter 20 and the ultrasonic treatment device 30 respectively, and configured to control the power of laser beam transmitted from the laser generator device and the frequency of ultrasonic wave emitted from the ultrasonic treatment device during the process of packaging.

In the packaging apparatus according to the embodiments of the present disclosure, when the laser emitting device emits laser beam to irradiate the frit so as to melt it, the ultrasonic treatment device is then configured to perform the ultrasonic treatment on the frit. By means of the cavity effect of ultrasonic wave vibration, an air bubble in the melted frit has its diameter and rising speed continuously increased so that the air bubble is discharged rapidly from the frit and the packaging yield is thus improved.

The foregoing are merely exemplary embodiments of the disclosure, but are not used to limit the protection scope of the disclosure. The protection scope of the disclosure shall be defined by the attached claims.

The present disclosure claims priority of Chinese Patent Application No. 201510587460.3 filed on Sep. 15, 2015, the disclosure of which is hereby entirely incorporated by reference as a part of the present disclosure.

1. A packaging method comprising:
forming a frit on a first substrate;
affixing a second substrate to the first substrate in position; and
irradiating the frit by laser beam so as to melt the frit;
wherein the method further comprises performing an ultrasonic treatment on the frit by means of ultrasonic wave when the frit being melted.

2. The packaging method according to claim 1, wherein the ultrasonic wave has a frequency in a range of 20 kHz to 60 kHz.

3. The packaging method according to claim 1, wherein the first substrate is an OLED array substrate and the second substrate is a cover glass.

4. The packaging method according to claim 1, wherein the frit is irradiated by the laser light from a side of the second substrate away from the first substrate, and the ultrasonic treatment is performed on the frit by use of the ultrasonic wave from a side of the first substrate away from the second substrate.

5. The packaging method according to claim 2, wherein the first substrate is an OLED array substrate and the second substrate is a cover glass.

6. The packaging method according to claim 2, wherein the frit is irradiated by the laser light from a side of the second substrate away from the first substrate, and the ultrasonic treatment is performed on the frit by use of the ultrasonic wave from a side of the first substrate away from the second substrate.

7. The packaging method according to claim 3, wherein the frit is irradiated by the laser light from a side of the second substrate away from the first substrate, and the ultrasonic treatment is performed on the frit by use of the ultrasonic wave from a side of the first substrate away from the second substrate.

8. A display panel comprising a first substrate and a second substrate which are packaged together by the method according to claim 1.

9. The display panel according to claim 8, wherein the first substrate is an OLED array substrate and the second substrate is a cover glass.

10. A display device comprising the display panel according to claim 8.

11. A packaging apparatus comprising a laser emitting device configured to emit laser beam for irradiating a frit between a first substrate and a second substrate so as to melt the frit, wherein the packaging apparatus further comprises an ultrasonic treatment device configured to perform an ultrasonic treatment on the frit by ultrasonic wave when the frit being melted.

12. The packaging apparatus according to claim 11, further comprising a control device configured to control power of the laser light and frequency of the ultrasonic wave.

13. The packaging apparatus according to claim 11, wherein the ultrasonic treatment device is an ultrasonic vibration generator.
